(19) United States
(12) Patent Application Publication
(10) Pub. No.: US 2010/0304279 A1
(43) Pub. Date: Dec. 2, 2010

(54) MANUFACTURING METHOD OF PHASE SHIFT MASK, CREATING METHOD OF MASK DATA OF PHASE SHIFT MASK, AND MANUFACTURING METHOD OF SEMICONDUCTOR DEVICE

(76) Inventors: Akiko MIMOTOGI, Kanagawa (JP); Satoshi Tanaka, Kanagawa (JP); Masanori Takahashi, Kanagawa (JP); Yoko Takekawa, New York, NY (US); Takamasa Takaki, Kanagawa (JP); Katsuyoshi Kodera, Kanagawa (JP); Hideichi Kawaguchi, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/708,944

(22) Filed: Feb. 19, 2010

(30) Foreign Application Priority Data
May 29, 2009 (JP) 2009-130892

(51) Int. Cl. G03F 1/00; G03F 7/20; G06K 9/00

(52) U.S. Cl. 430/5; 430/319; 382/144

(57) ABSTRACT

A phase shift mask having a plurality of mask patterns or mask data thereof is prepared, and an overlapped focus range in each of the mask patterns in a case where a result of exposure to each of the mask patterns, obtained by an exposure experiment or a lithography simulation, meets a desired dimension is obtained. A digging depth is determined at discretion based on the obtained overlapped focus range.

### CROSS-REFERENCE TO RELATED APPLICATIONS

This application is based upon and claims the benefit of priority from the prior Japanese Patent Application No. 2009-130892, filed on May 29, 2009; the entire contents of which are incorporated herein by reference.

### BACKGROUND OF THE INVENTION

1. Field of the Invention

The present invention relates to a manufacturing method of a phase shift mask, a creating method of a mask data of a phase shift mask, and a manufacturing method of a semiconductor device.

2. Description of the Related Art

In a manufacturing process for a semiconductor device, higher resolution above a resolution limit determined from an exposure wavelength is demanded in a photolithography step as patterns become finer. To satisfy this demand, a so-called phase shift mask that increases resolution by providing a phase difference between lights transmitted through adjacent regions is proposed (see International Publication No. 06/064679, for example). An attenuated phase shift mask (AttPSM) is known as an example of the phase shift mask, which has a small optical transparency in a light shielding film, thereby making phases of transmitted lights opposite. The thickness of the light shielding film is adjusted so that a phase difference between lights transmitted through a region including the light shielding film and a region including no light shielding film, adjacent to each other on the phase shift mask, becomes 180 degrees.

An exposure technique using immersion method is developed, which applies an ArF excimer laser beam (having a central wavelength of 193 nanometers) as an exposure light to form a finer pattern. The exposure technique using immersion method enables a lithography process at an ultrahigh numerical aperture (NA), for example, with a projector lens having an NA of about 1.3. In this case, a pattern size on a photomask is equivalent to a wavelength of the exposure light. Accordingly, influences of events caused by a structure of the photomask, particularly a film thickness upon phase shift, such as a waveguide effect on the photomask and shielding of the exposure light by oblique incidence of the exposure light to the photomask become problems. An amount of phase shift on a pupil varies according to pitches or pattern dimensions of mask patterns, and therefore it is difficult to adjust focus for a plurality of mask patterns.

### BRIEF SUMMARY OF THE INVENTION

A manufacturing method of phase shift mask according to an embodiment of the present invention comprises: preparing a phase shift mask including a transmitting unit that transmits an exposure light and a light shielding unit that shields at least part of the exposure light, and having a plurality of mask patterns in which at least either one of pitches and pattern dimensions thereof are different, or mask data of the phase shift mask; performing an exposure experiment through the phase shift mask having a dug portion formed in a region for configuring the transmitting unit, or a lithography simulation using the mask data; obtaining an overlapped focus range in each of the plural mask patterns in a case where a result of exposure to each of the mask patterns, obtained by the exposure experiment or the lithography simulation, meets a desired dimension; and forming a dug portion with a digging depth determined at discretion based on the obtained overlapped focus range.

A creating method of mask data of phase shift mask according to an embodiment of the present invention comprises: preparing a phase shift mask including a transmitting unit that transmits an exposure light and a light shielding unit that shields at least part of the exposure light, and having a plurality of mask patterns in which at least either one of pitches and pattern dimensions thereof are different, or mask data of the phase shift mask; performing an exposure experiment through the phase shift mask having a dug portion formed in a region for configuring the transmitting unit, or a lithography simulation using the mask data; obtaining an overlapped focus range in each of the plural mask patterns in a case where a result of exposure to each of the mask patterns, obtained by the exposure experiment or the lithography simulation, meets a desired dimension; and creating mask data in a case where a dug portion with a digging depth determined at discretion based on the obtained overlapped focus range is formed.

A manufacturing method of semiconductor device according to an embodiment of the present invention comprises: forming a photosensitive film on a semiconductor substrate; applying an exposure light through a phase shift mask, to form a pattern on the photosensitive film; processing the semiconductor substrate by using the photosensitive film having the pattern formed thereon as a mask; preparing a phase shift mask including a transmitting unit that transmits an exposure light and a light shielding unit that shields at least part of the exposure light, and having a plurality of mask patterns in which at least either one of pitches and pattern dimensions thereof are different, or mask data of the phase shift mask; performing an exposure experiment through the phase shift mask having a dug portion formed in a region for configuring the transmitting unit, or a lithography simulation using the mask data; obtaining an overlapped focus range in each of the plural mask patterns in a case where a result of exposure to each of the mask patterns, obtained by the exposure experiment or the lithography simulation, meets a desired dimension; and forming a dug portion with a digging depth determined at discretion based on the obtained overlapped focus range.

### BRIEF DESCRIPTION OF THE DRAWINGS

FIG. 1 is a schematic cross-sectional view of a phase shift mask manufactured by a manufacturing method according to a first embodiment of the present invention;

FIG. 2 is a schematic diagram of a projection exposure device that performs exposure through a phase shift mask;

FIG. 3 is a graph of an example of a relation between a phase difference between a 0th-order diffracted light and a 1st-order diffracted light, and a half pitch;

FIG. 4 is a graph of an example of results obtained by measuring an optical image of a photomask by an AIMS;

FIG. 5 is a graph of an example of results of experiments performed by an exposure device;

FIG. 6 is a flowchart of a procedure of determining an optimal value of a depth of dug portions;

FIG. 7 is a schematic diagram for explaining an example of a selection mask pattern;

FIG. 8 is a schematic diagram for explaining another example of a selection mask pattern;

FIG. 9 is a schematic cross-sectional view of a testing mask for explaining formation of dug portions into a testing substrate;

FIG. 10 is a graph of relations between a CD and a focus when a digging depth is changed;

FIG. 11 is a schematic cross-sectional view of a phase shift mask manufactured by a manufacturing method according to a second embodiment of the present invention; and

FIGS. 12A to 12C are schematic cross-sectional views of a phase shift mask manufactured by a manufacturing method according to a third embodiment of the present invention.

### DETAILED DESCRIPTION OF THE INVENTION

Exemplary embodiments of manufacturing method of phase shift mask, creating method of mask data of phase shift mask, and manufacturing method of semiconductor device according to the present invention will be explained below in detail with reference to the accompanying drawings. The present invention is not limited to the embodiments.

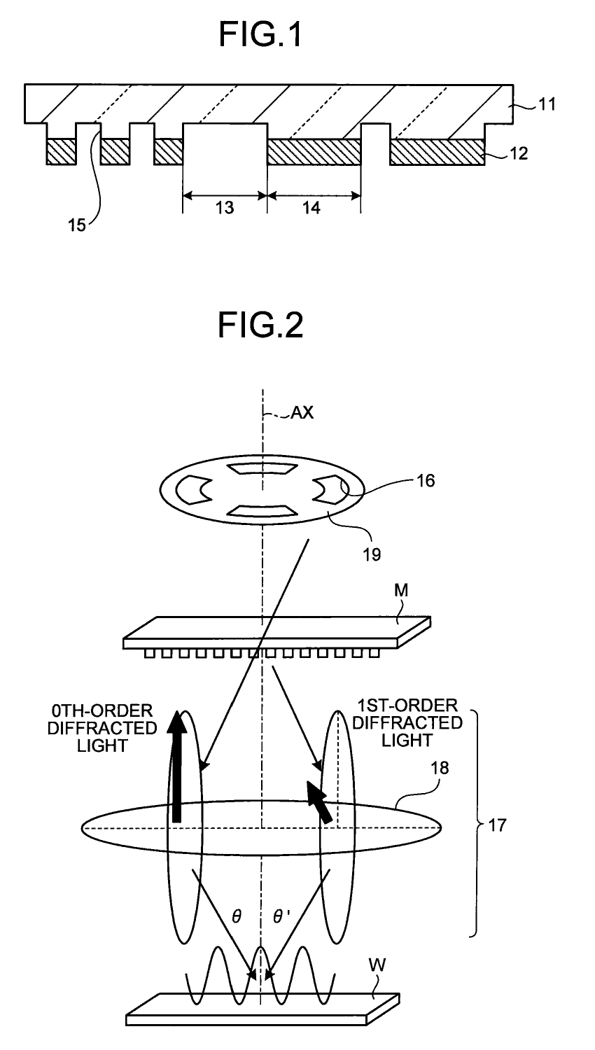

FIG. 1 is a schematic cross-sectional view of a phase shift mask manufactured by a manufacturing method according to a first embodiment of the present invention. The phase shift mask includes a transparent substrate 11 and a patterned light shielding film 12. The transparent substrate 11 is made of a member transparent to an exposure light, for example, a quartz member. The light shielding film 12 is provided on a surface of the transparent substrate 11. A region of the phase shift mask, in which the light shielding film 12 is formed, acts as a light shielding unit 14 that shields at least part of the exposure light. A region of the phase shift mask, from which the light shielding film 12 is removed, acts as a transmitting unit 13 that transmits the exposure light. A plurality of mask patterns at least either one of pitches and pattern dimensions of which are different are formed on the phase shift mask.

The light shielding unit 14 of the phase shift mask shields most of the incident exposure light and transmits a small part, for example about 6% of the incident exposure light. The phase shift mask is an attenuated phase shift mask that inverts a phase of the transmitted light by the light shielding film 12 having a small optical transparency. The light shielding film 12 is made of molybdenum silicide, for example. A thickness of the light shielding film 12 is adjusted so that a phase difference of lights transmitted through the transmitting unit 13 and the light shielding unit 14 adjacent to each other becomes 180 degrees. Dug portions 15 are formed in the transmitting unit 13 of the transparent substrate 11. The dug portions 15 are formed by digging regions on the surface of the transparent substrate 11, in which the light shielding film 12 is formed.

Problems of a phase shift mask manufactured by a conventional manufacturing method are explained with reference to FIGS. 2 to 5. FIG. 2 is a schematic diagram of a projection exposure device that performs exposure through a phase shift mask M. The projection exposure device transmits a light from a light source (not shown) through an aperture stop 19 having four apertures 16 formed therein to cause an exposure light to be obliquely incident on the phase shift mask M. The apertures 16 are formed at positions other than an optical axis AX. The phase shift mask M produces a 0th-order diffracted light and a 1st-order diffracted light. A projection optical system 17 (configuration thereof is not shown in FIG. 2) causes the 0th-order diffracted light and the 1st-order diffracted light to interfere with each other on a wafer W. It is assumed that a Fourier transformation plane of a mask pattern of the phase shift mask M is located at a position of a pupil 18 of the projection optical system 17.

A maximum incident angle of the exposure light incident on the phase shift mask M can be increased by increasing an NA of the projection optical system 17. However, when the incident angle of the exposure light incident on the phase shift mask M is increased, influences of events caused by a structure of the phase shift mask M, particularly a film thickness, on phase shift such as a waveguide effect of the phase shift mask M and shielding of the exposure light by a mask pattern due to oblique incidence of the exposure light become problems.

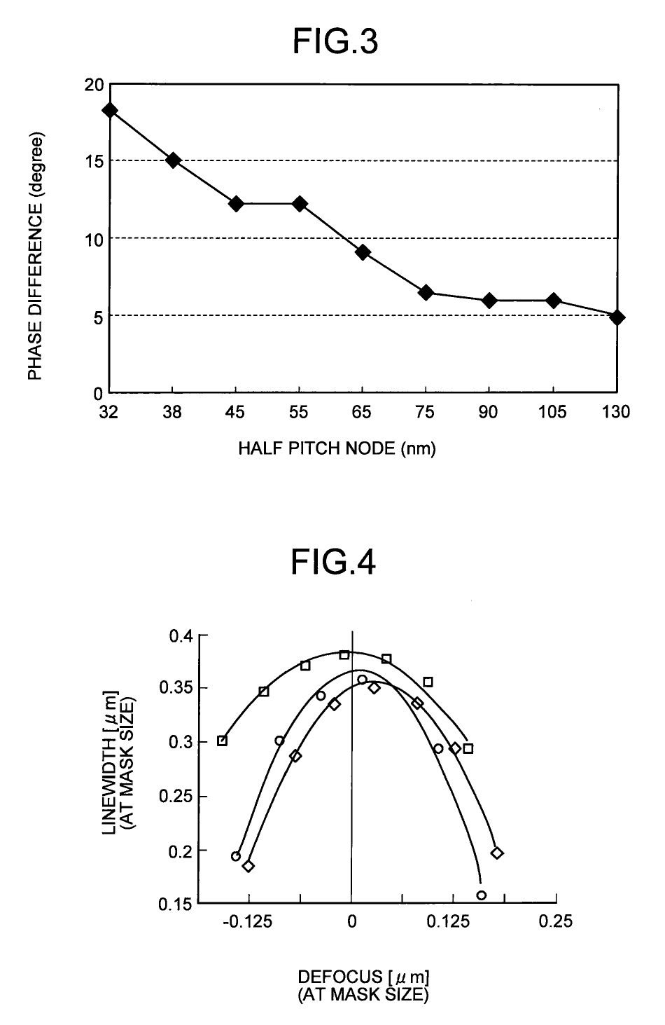

FIG. 3 is a graph of an example of a relation between a phase difference between a 0th-order diffracted light and a 1st-order diffracted light, and a half pitch. In this example, incident angles of the 0th-order and 1st-order diffracted lights are set to be symmetrical to an optical axis in a 1:1 line-and-space pattern. The phase difference on the vertical axis represents an amount of deviation from a state where the 0th-order diffracted light and the 1st-order diffracted light have an ideal phase difference, that is, a state where the phase difference therebetween is zero degrees or 180 degrees. When a pitch of a mask pattern is reduced, the phase shift amount is increased.

FIG. 4 is a graph of an example of results that are obtained by measuring an optical image of a photomask including a plurality of mask patterns using an Aerial Imaging Measurement System (AIMS). With the AIMS, the optical image of the photomask can be directly observed, and accordingly influences of the photomask on focusing can be measured with effects of the wafer W eliminated. In this example, a focus dependency of a line width on an optical image is measured with respect to plural mask patterns in which at least either one of pitches and pattern dimensions are different. The vertical axis represents a line width of an optical image, and the horizontal axis represents a defocus (deviation from a focus position as a reference). A local maximum value of each curve shows a center position of the focus. These results include defocuses of about 30 to 40 nanometers resulting from the photomask structure.

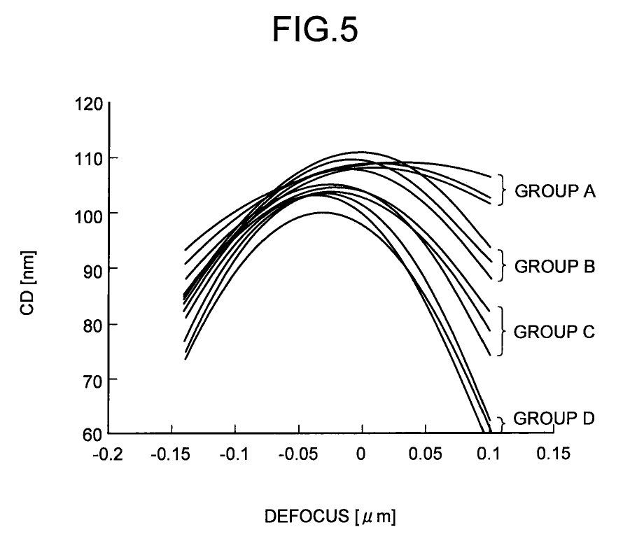

FIG. 5 is a graph of an example of results of experiments performed by the exposure device. The vertical axis represents a pattern dimension (CD: Critical Dimension) of a pattern formed on the wafer W. In the case of a linear pattern, the CD is a line width. The horizontal axis represents a defocus. Pattern dimensions at target positions in respective patterns are plotted, and then deviated center positions of focuses are found.

The first embodiment is characterized such that the depth of the dug portions 15 (see FIG. 1) is optimized so that amounts of phase shift in the exposure light due to the waveguide effect caused by the photomask structure or the like become approximately the same near the plural mask patterns.

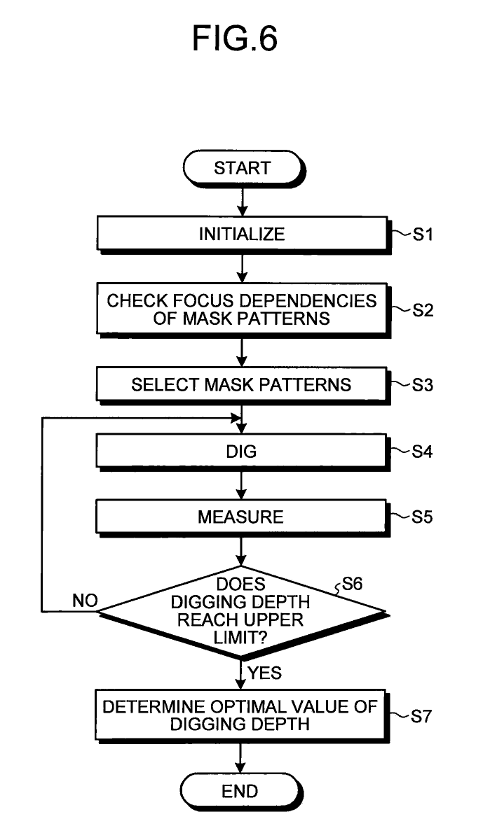

FIG. 6 is a flowchart of a procedure of determining an optimum value of the depth of the dug portions. At Step S1, illumination conditions required for exposure are determined, and a phase shift mask including the plural mask patterns as management targets, or mask data thereof is prepared for initialization.

At Step S2, a measurement to check focus dependencies of the mask patterns is performed. When the phase shift mask is prepared at Step S1, the focus dependencies are checked in an exposure experiment by exposure through the phase shift mask. In the exposure experiment, pattern dimensions are determined by measuring a resist pattern formed by exposure.

When the mask data for the phase shift mask is prepared at Step S1, the focus dependencies are checked in a lithography simulation. In the lithography simulation, optical image calculation or mask image observation is performed, for example. When the optical image calculation is performed, the pattern dimensions are determined by estimating a resist pattern from an optical image. A pattern dimension, a positional relation, or the like in a desired design is used as data inputted for the simulation, for example. When the mask image observation is performed, the mask pattern dimensions are determined by estimating a resist pattern from a result of observation by the AIMS, for example. The pattern dimension can be determined by performing at least one of the exposure experiment, the optical image calculation, and the mask image observation. The pattern dimension can be determined by performing a combination thereof.

At Step S3, at least two of the plural mask patterns are selected as selection mask patterns. Mask patterns that provide smallest overlapped focus ranges when a result of the exposure in the exposure experiment or the lithography simulation before forming dug portions meets a desired pattern dimension are selected as the selection mask patterns.

It is assumed for example that the measurement result as shown in FIG. 5 is obtained by the exposure experiment. In this result, the mask patterns are classified into four general groups A, B, C, and D having closer relations between the CD and the defocus. It is assumed that a desired pattern dimension is met in a predetermined focus range around a center position of a focus. In the mask patterns classified into the group A and the mask patterns classified into the group D, the overlapped focus ranges when the desired pattern dimension is met are the smallest.

In the group A, however, curves are shallower than those of other groups, and variations in the CD caused by changes in the focus are relatively small. Accordingly, even when the center position of the focus is deviated, margins to other patterns can be obtained relatively easily. Thus, one mask pattern from each of the groups B and D, in which the variations in the CD with respect to the focus are large and the overlapped focus range when the desired pattern dimension is met is the smallest, is selected as the selection mask patterns.

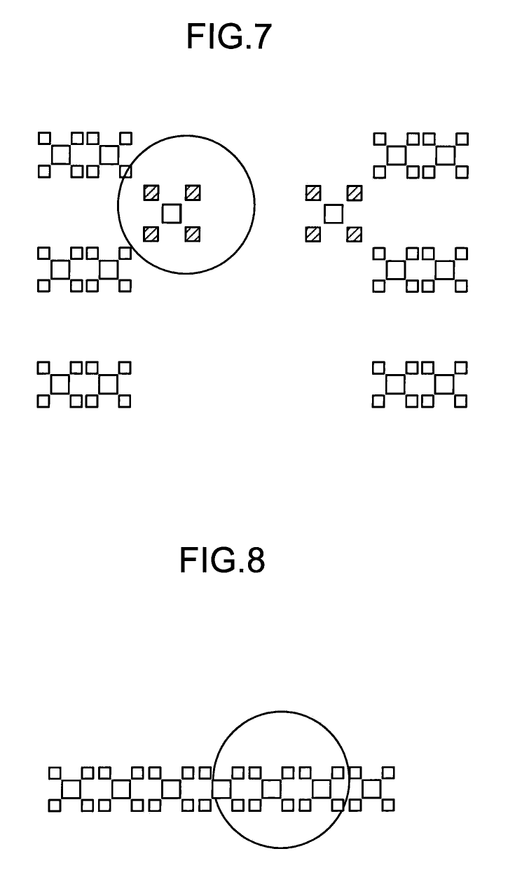

FIGS. 7 and 8 are schematic diagrams for explaining examples of the selection mask pattern. In these examples, mask patterns for forming a minute rectangular hole in a wafer are management targets. For example, a mask pattern circled in FIG. 7 is formed in isolation from other patterns to form a hole isolated from those therearound in a wafer. A mask pattern circled in FIG. 8 is formed to have a periodicity in one direction to form holes arranged periodically in the direction in a wafer. In this way, mask patterns that are arranged in greatly different manners tend to provide a small overlapped focus range when a desired pattern dimension is met.

When the phase shift mask is prepared at Step S1, dug portions are formed in regions that configure a transmitting unit of a testing substrate at Step S4. At Step S5, a measurement to check the focus dependencies of the selection mask patterns is performed. At Step S6, it is determined whether the depth of the dug portions thus formed reaches an upper limit.

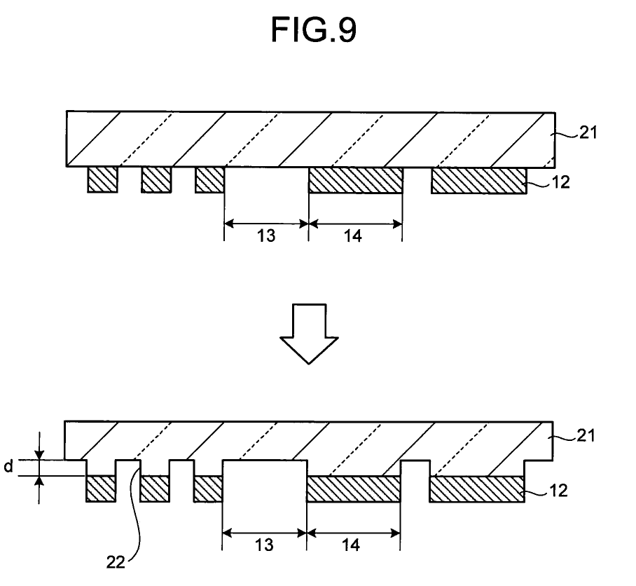

FIG. 9 is a schematic cross-sectional view of a testing mask for explaining formation of dug portions 22 into a testing substrate 21. The measurement to check the focus dependencies is performed while a digging depth d of the dug portions 22 is increased in a stepwise manner. The digging depth d is a depth based on a height of a region of the testing substrate 21 on which the light shielding film 12 is formed. An amount of one digging at Step S4 is obtained by equally dividing the upper limit of the digging depth d into plural pieces.

When the dug portions 22 are formed at first Step S4 and the measurement at Step S5 is finished, the digging depth d is lower than the upper limit (No at Step S6), and then the process returns to Step S4 to perform second digging. The processes from Steps S4 to S6 are repeated until the digging depth d of the dug portions 22 reaches the upper limit. The upper limit of the digging depth d can have an arbitrary value and can be properly set. It is only necessary that the dug portions 22 be formed at least in regions including the selection mask patterns at Step S4, and the present invention is not limited to the case where the dug portions 22 are formed across the testing substrate 21.

When the digging depth d of the dug portions 22 reaches the upper limit (YES at Step S6), an optimum value of the digging depth d is determined. Among measurement results obtained each time the digging depth d is changed in a stepwise manner, a digging depth d obtained when an overlapped focus range when the desired pattern dimension is met is the largest is determined as the optimum value (Step S7). The process for determining the optimum value of the digging depth d is then ended. The phase shift mask is manufactured by forming a film of a light shielding material on the transparent substrate 11 as a material substrate, patterning the film, and then forming the dug portions 15 with the optimum digging depth determined in the above procedure.

Also when the lithography simulation is performed, a digging depth at the time of a largest overlapped focus range is determined as the optimum value based on exposure results obtained each time a digging depth of the phase shift mask is changed. Data of a mask including the dug portions with the optimum digging depth is created, and the phase shift mask is manufactured based on the created mask data. When the optimum value of the digging depth is determined by the lithography simulation, an amount of variations in the digging depth d can be set according to optimization algorithm. Accordingly, the amount of variations in the digging depth d is not limited to the one in the case where the digging depth is changed in a stepwise manner.

In the first embodiment, the digging depth is changed until when the digging depth reaches the upper limit, and a digging depth that provides a largest focus range is adopted. However, the present invention is not limited thereto. For example, a digging depth that provides a largest overlapped focus range during an arbitrary number of measurements to obtain a focus range can be adopted. Alternatively, a digging depth that provide an overlapped focus range meeting an admissibility condition during an arbitrary number of measurements can be adopted. When an overlapped focus range even in a case where one measurement is performed to set a digging depth is larger than that in a case where no dug portion is formed, such a digging depth can be adopted. In the first embodiment, at least dug portions with a digging depth determined at discretion according to the obtained overlapped focus range are formed, or mask data at the formation of the dug portions is created.

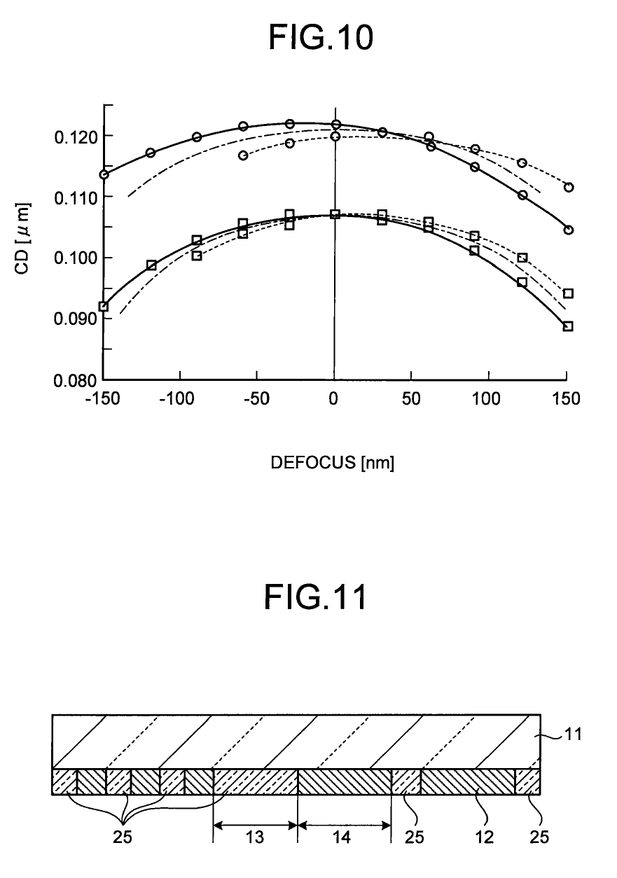

FIG. 10 is a graph of relations between the CD and the focus obtained when the digging depth is changed. Plotted outline circles represent results of a measurement of a relation between the CD and the focus in a mask pattern 1. Plotted outline squares represent results of a measurement of a relation between the CD and the focus in a mask pattern 2. Broken-line graphs in the mask patterns 1 and 2 represent relations between the CD and the focus when no dug portion is formed. Solid-line graphs in the mask patterns 1 and 2 represent relations between the CD and the focus when the digging depth d is 10 nanometers. A dashed-dotted-line graph located between the solid-line graph and the broken-line graph obtained by plotting the outline circles represents a relation between the CD and the focus when the digging depth d is 5 nanometers in the mask pattern 1. A dashed-dotted-line graph located between the solid-line graph and the broken-line graph obtained by plotting the outline squares represents a relation between the CD and the focus when the digging depth d is 5 nanometers in the mask pattern 2.

It is assumed that a center position of the focus in the mask pattern 1 is 25 nanometers and a center position of the focus in the mask pattern 2 is 14.29 nanometers when no dug portion is formed. In this case, a difference in the center position of the focus between the mask patterns 1 and 2 is 10.71 nanometers.

It is assumed that the center position of the focus in the mask pattern 1 is 0 nanometer and the center position of the focus in the mask pattern 2 is 4 nanometers when the digging is performed until the digging depth d reaches 5 nanometers. In this case, the difference in the center position of the focus between the mask patterns 1 and 2 is 4 nanometers.

It is assumed that the center position of the focus in the mask pattern 1 is −25.0 nanometers and the center position of the focus in the mask pattern 2 is −6.25 nanometers when the digging is performed until the digging depth d reaches 10 nanometers. In this case, the difference in the center position of the focus between the mask patterns 1 and 2 is 18.75 nanometers.

A largest overlapped focus range between the mask patterns 1 and 2 at the desired pattern dimension is obtained when the difference in the center position of the focus is the smallest. From the above results, the difference in the center position of the focus is the smallest when the digging depth d is 5 nanometers. When the digging depth d is 5 nanometers, the overlapped focus range between the mask patterns 1 and 2 at the desired pattern dimension is the largest. Therefore, when the dug portions 15 with the digging depth 5 of 5 nanometers are formed in the phase shift mask, defocus can be adjusted so that the influences of the waveguide effects in the mask patterns 1 and 2 become similar to each other.

When the mask patterns that provide the smallest overlapped focus range at the desired pattern dimension are selected as the selection mask patterns from the plural mask patterns to obtain an optimum value of the digging depth d, defocus adjustment that produces similar waveguide effects in all the plural mask patterns can be performed. In this way, the defocus resulting from the structure of the photomask can be reduced in the plural mask patterns. When the focus ranges are kept within a focus margin of the exposure device to meet the desired pattern dimensions of all the plural mask patterns, all the mask patterns can be resolved with a satisfactory margin.

A method of manufacturing a semiconductor device according to the first embodiment is then explained. The phase shift mask manufactured by the above steps is positioned in an optical path of the exposure device. A semiconductor substrate having a photosensitive film formed thereon is placed on a wafer stage and irradiated with an exposure light through the phase shift mask. The exposure through the phase shift mask can reduce defocus in the plural mask patterns, and enables to project the patterns at high resolution and with reliability. Further, a photosensitive film pattern is formed by developing the photosensitive film exposed in the manner mentioned above, and the semiconductor substrate is etched by using the photosensitive film pattern as a mask. The semiconductor device can be manufactured in this way. The method of manufacturing the phase shift mask described in the first embodiment can be applied to manufacture a phase shift mask other than the attenuated phase shift mask.

FIG. 11 is a schematic cross-sectional view of a phase shift mask manufactured by a manufacturing method according to a second embodiment of the present invention. The second embodiment is characterized such that a phase shift mask including transparent members 25 in the transmitting unit 13 is used. The transparent member 25 is replaced with the dug portion 15 (see FIG. 1) in the first embodiment. Like parts as those in the first embodiment are denoted by like reference numerals and redundant explanations thereof will be omitted. The transparent member 25 is filled between the light shielding films 12. An extinction coefficient k of the transparent member 25 satisfies a following expression (1).

|k|<0.1 (1)

The transparent member 25 is a member that satisfies the expression (1), for example, a transparent resin member. It is preferable that the extinction coefficient k be closer to zero because influences on transmittance can be reduced. With the transparent member 25, the amount of phase shift of the exposure light due to the waveguide effect is cancelled near the plural mask patterns when the exposure light is applied through the phase shift mask. Accordingly, defocus in the plural mask patterns can be reduced and the patterns can be projected at high resolution and with reliability.

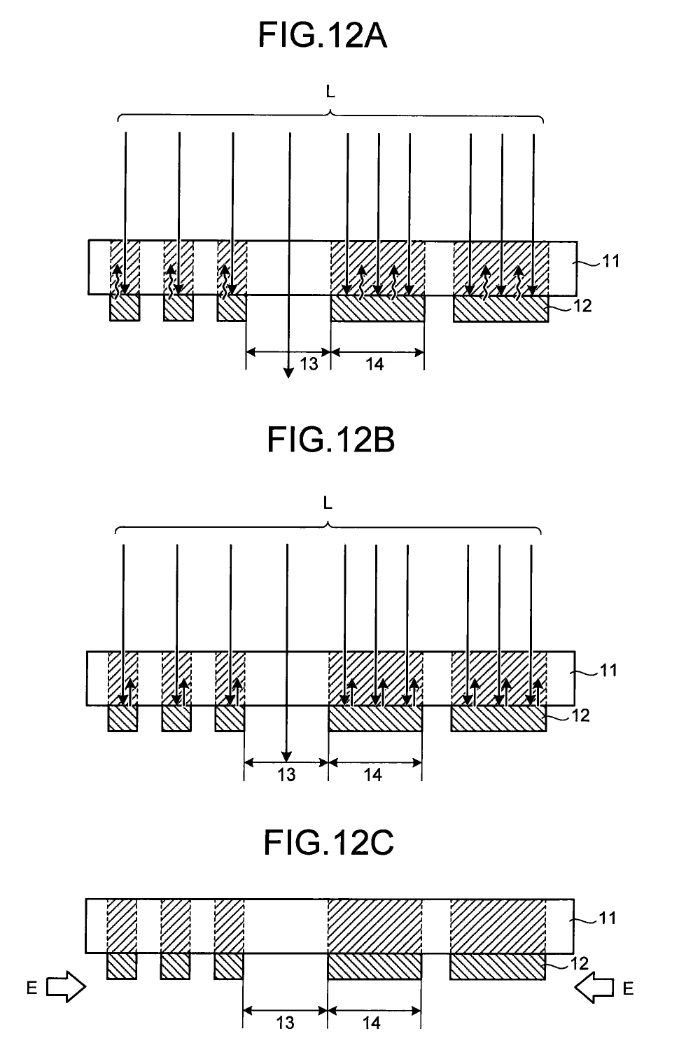

FIGS. 12A to 12C are schematic cross-sectional views of a phase shift mask manufactured by a manufacturing method according to a third embodiment of the present invention. The third embodiment is characterized such that a phase shift mask having an adjusted refractive index of a region for configuring the transmitting unit 13 of the transparent substrate 11 is used. In the region for configuring the transmitting unit 13 of the transparent substrate 11, the refractive index is adjusted, without the dug portions 15 in the first embodiment (see FIG. 1) formed. Like parts as those in the first embodiment are denoted by like reference numerals and redundant explanations thereof will be omitted.

In a phase shift mask shown in FIG. 12A, the refractive index of the transparent substrate 11 is adjusted by using a difference in temperatures produced in the transparent substrate 11. When the phase shift mask is irradiated with an exposure light L, temperature distribution is produced on the transparent substrate 11 according to densities of the mask patterns. When the mask pattern is denser, the temperature is increased by the exposure light L. The refractive index of the transparent substrate 11 is adjusted according to changes in the temperature due to the exposure light L. The application of the exposure light L is not the only method of producing a difference in the temperature on the transparent substrate 11 but heating or cooling by other methods can be utilized.

In a phase shift mask shown in FIG. 12B, the refractive index is adjusted by using changes in a nonlinear refractive index according to irradiation intensity of the exposure light L. When the phase shift mask is irradiated with the exposure light L, the irradiation intensity distribution of the exposure light L is produced on the transparent substrate 11 according to the densities of the mask patterns. When the mask pattern is denser, the phase shift mask is irradiated with the exposure light L more intensely. The nonlinear refractive index of the transparent substrate 11 is changed according to changes in the irradiation intensity of the exposure light L, so that the refractive index is adjusted.

In a phase shift mask shown in FIG. 12C, the refractive index is adjusted by using application of an electromagnetic field E. When the electromagnetic field E is applied to the phase shift mask, distribution of an applied electric or magnetic field is produced on the transparent substrate 11 according to the densities of the mask patterns. The refractive index of the transparent substrate 11 is adjusted according to changes in the applied electric or magnetic field.

When the refractive index of the transparent substrate 11 is adjusted by applying any one of the three manners as shown in FIGS. 12A to 12C, the phase shift amount of the exposure light due to the waveguide effect is cancelled near the plural mask patterns when the exposure light is applied through the phase shift mask. In this way, defocus in the plural mask patterns can be reduced and the patterns can be projected at high resolution and with reliability.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A manufacturing method of a phase shift mask, comprising:
preparing a phase shift mask including a transmitting unit that transmits an exposure light and a light shielding unit that shields at least part of the exposure light, and having a plurality of mask patterns in which at least either one of pitches and pattern dimensions thereof are different, or mask data of the phase shift mask;
performing an exposure experiment through the phase shift mask having a dug portion formed in a region for configuring the transmitting unit, or a lithography simulation using the mask data;
obtaining an overlapped focus range in each of the plural mask patterns in a case where a result of exposure to each of the mask patterns, obtained by the exposure experiment or the lithography simulation, meets a desired dimension; and
forming a dug portion with a digging depth determined at discretion based on the obtained overlapped focus range.

2. The manufacturing method of a phase shift mask according to claim 1, comprising adopting the digging depth in a case where the overlapped focus range meets a predetermined admissibility condition.

3. The manufacturing method of a phase shift mask according to claim 1, comprising:
performing the exposure experiment or the lithography simulation each time the digging depth of the dug portion is changed; and
determining the digging depth in a case where the overlapped focus range is largest, as an optimum value.

4. The manufacturing method of a phase shift mask according to claim 1, comprising:
performing an exposure experiment through the phase shift mask before the dug portion is formed, or a lithography simulation using mask data of the phase shift mask; and
selecting at least two mask patterns in which the overlapped focus range in a case where the exposure result obtained by the exposure experiment or the lithography simulation meets the desired dimension is smallest, as selection mask patterns, and performing the exposure experiment or the lithography simulation in a case where the dug portion is formed.

5. The manufacturing method of a phase shift mask according to claim 1, comprising performing at least one of a measurement of a resist pattern in the exposure experiment, and an estimation of a resist pattern by optical image calculation and an estimation of a resist pattern by mask image observation in the lithography simulation.

6. A method of creating mask data of a phase shift mask, comprising:
preparing a phase shift mask including a transmitting unit that transmits an exposure light and a light shielding unit that shields at least part of the exposure light, and having a plurality of mask patterns in which at least either one of pitches and pattern dimensions thereof are different, or mask data of the phase shift mask;
performing an exposure experiment through the phase shift mask having a dug portion formed in a region for configuring the transmitting unit, or a lithography simulation using the mask data;
obtaining an overlapped focus range in each of the plural mask patterns in a case where a result of exposure to each of the mask patterns, obtained by the exposure experiment or the lithography simulation, meets a desired dimension; and
creating mask data in a case where a dug portion with a digging depth determined at discretion based on the obtained overlapped focus range is formed.

7. The creating method of mask data according to claim 6, comprising adopting the digging depth in a case where the overlapped focus range meets a predetermined admissibility condition.

8. The creating method of mask data according to claim 6, comprising:
performing the exposure experiment or the lithography simulation each time the digging depth of the dug portion is changed; and
determining the digging depth in a case where the overlapped focus range is largest, as an optimum value.

9. The creating method of mask data according to claim 6, comprising:
performing an exposure experiment through the phase shift mask before the dug portion is formed, or a lithography simulation using mask data of the phase shift mask; and
selecting at least two mask patterns in which the overlapped focus range in a case where the exposure result obtained by the exposure experiment or the lithography simulation meets the desired dimension is smallest, as selection mask patterns, and performing the exposure experiment or the lithography simulation in a case where the dug portion is formed.

10. The creating method of mask data according to claim 6, comprising performing at least one of a measurement of a resist pattern in the exposure experiment, and an estimation of a resist pattern by optical image calculation and an estimation of a resist pattern by mask image observation in the lithography simulation.

11. A manufacturing method of a semiconductor device comprising:
forming a photosensitive film on a semiconductor substrate;
applying an exposure light through a phase shift mask, to form a pattern on the photosensitive film;
processing the semiconductor substrate by using the photosensitive film having the pattern formed thereon as a mask;
preparing a phase shift mask including a transmitting unit that transmits an exposure light and a light shielding unit that shields at least part of the exposure light, and having a plurality of mask patterns in which at least either one of pitches and pattern dimensions thereof are different, or mask data of the phase shift mask;
performing an exposure experiment through the phase shift mask having a dug portion formed in a region for configuring the transmitting unit, or a lithography simulation using the mask data;
obtaining an overlapped focus range in each of the plural mask patterns in a case where a result of exposure to each of the mask patterns, obtained by the exposure experiment or the lithography simulation, meets a desired dimension; and
forming a dug portion with a digging depth determined at discretion based on the obtained overlapped focus range.

12. The manufacturing method of a semiconductor device according to claim 11, comprising adopting the digging depth in a case where the overlapped focus range meets a predetermined admissibility condition.

13. The manufacturing method of a semiconductor device according to claim 11, comprising:
performing the exposure experiment or the lithography simulation each time the digging depth of the dug portion is changed; and
determining the digging depth in a case where the overlapped focus range is largest, as an optimum value.

14. The manufacturing method of a semiconductor device according to claim 11, comprising:
performing an exposure experiment through the phase shift mask before the dug portion is formed, or a lithography simulation using mask data of the phase shift mask; and
selecting at least two mask patterns in which the overlapped focus range in a case where the exposure result obtained by the exposure experiment or the lithography simulation meets the desired dimension is smallest, as selection mask patterns, and performing the exposure experiment or the lithography simulation in the case where the dug portion is formed.

15. The manufacturing method of a semiconductor device according to claim 11, comprising performing at least one of a measurement of a resist pattern in the exposure experiment, and an estimation of a resist pattern by optical image calculation and an estimation of a resist pattern by mask image observation in the lithography simulation.

16. The manufacturing method of a phase shift mask according to claim 1, comprising providing a transparent member with an extinction coefficient an absolute value of which is smaller than 0.1 in the region for configuring the transmitting unit, instead of forming the dug portion, thereby canceling an amount of phase shift in the exposure light due to a waveguide effect near the plural mask patterns.

17. The manufacturing method of a phase shift mask according to claim 1, comprising adjusting a refractive index in the region for configuring the transmitting unit of the transparent substrate, instead of forming the dug portion, thereby canceling an amount of phase shift in the exposure light due to a waveguide effect near the plural mask patterns.

18. The manufacturing method of a phase shift mask according to claim 17, wherein the refractive index is adjusted by using a difference in temperatures produced on the transparent substrate.

19. The manufacturing method of a phase shift mask according to claim 17, wherein the refractive index is adjusted by using a change in a nonlinear refractive index according to an irradiation intensity of the exposure light.

20. The manufacturing method of a phase shift mask according to claim 17, wherein the refractive index is adjusted by using application of an electromagnetic field.
